(19) United States
(12) Patent Application Publication
(10) Pub. No.: US 2004/0018739 A1
(43) Pub. Date: Jan. 29, 2004

(54) Methods for etching using building blocks

(75) Inventors: Farid Abooameri, Pleasanton, CA (US); Shashank C. Deshmukh, San Jose, CA (US); Meihua Shen, Fremont, CA (US); Stephanie S. Cheng, San Francisco, CA (US); Nicolas Gani, Milpitas, CA (US); Thorsten B. Lill, Santa Clara, CA (US)

Correspondence Address: APPLIED MATERIALS, INC., PATENT COUNSEL, MS/2061, Legal Affairs Department, P.O.BOX 450A, Santa Clara, CA, 95052, US

(73) Assignee: Applied Materials, Inc.

(21) Appl. No.: 10/206,252

(22) Filed: Jul. 26, 2002

(51) Int. Cl. H01L 21/302; H01L 21/461

(52) U.S. Cl. 438/709

(57) ABSTRACT

One embodiment of the present invention is a method used to fabricate an integrated circuit device on a wafer or substrate at a stage where a gate oxide is disposed over the wafer or substrate, a polysilicon layer is disposed thereover, a patterned hardmask is disposed thereover, a patterned antireflective coating is disposed thereover, and a patterned photoresist is disposed thereover, the method including steps of: (a) before stripping the photoresist, etching the polysilicon utilizing a first etch chemistry for a first period of time; and (b) etching the polysilicon utilizing a second etch chemistry for a second period of time.

### TECHNICAL FIELD OF THE INVENTION

One or more embodiments of the present invention pertain to methods for etching used, for example, and without limitation, in fabricating transistors in integrated circuit (“IC”) structures.

### BACKGROUND OF THE INVENTION

FIG. 1 shows a typical film stack structure used to fabricate a transistor on a wafer or substrate. As shown in FIG. 1, film stack structure 1400 includes: (a) gate oxide (“Gox”) layer 1010 that is formed on substrate 1000; (b) polysilicon layer 1020 that is formed over Gox 1010; (c) hardmask (“HM”) layer 1030 that is formed over polysilicon layer 1020 (for example, and without limitation, HM layer 1030 may be a silicon oxide layer formed using a deposition process wherein TEOS is a precursor (referred to as a “TEOS HM”) or it may be a silicon nitride layer) ; (d) BARC layer 1040 (as is well known, BARC or “bottom antireflective coating” is an organic antireflective coating that is typically produced by a spin-on process) that is formed over HM layer 1030; and (e) patterned photoresist (“PR”) layer 1050 that is formed over BARC layer 1040.

In accordance with prior art techniques, after PR layer 1050 is patterned, BARC layer 1040 and HM layer 1030 are etched, for example, and without limitation, in a DPS (“decoupled plasma source) polysilicon etch tool that is available from Applied Materials, Inc. of Santa Clara, Calif., to open polysilicon layer 1020. Then, PR layer 1050 and BARC layer 1040 are stripped before etching polysilicon layer 1020. Then, in accordance with one prior art technique, polysilicon layer 1020 is plasma etched using a “self-cleaning” 4-gas, fluorine-based etch chemistry using HM layer 1030 as a mask. In accordance with one such plasma etch technique, the 4-gas, fluorine-based etch chemistry includes HBr/Cl₂/CF₄/He-O₂. Note that the 4-gas, fluorine-based etch chemistry contains O₂ which provides selectivity with respect to Gox layer 1010. However, since PR layer 1050 scavenges O₂, PR layer 1050 is stripped prior to etching polysilicon layer 1020 and to provide a controlled process.

One problem encountered with the above-described prior art technique arises because of fabrication of dual gate transistors on the same wafer, i.e., n-doped and p-doped gates on the same wafer. This presents a problem due to etch rate differences between the two types of gates when using the 4-gas, fluorine-based etch chemistry.

Another problem encountered with the above-described prior art technique arises because typical present day designs call for thin HM layers. For example, in a typical present day design, a TEOS HM layer thickness is typically in a range from about 350 Å to about 800 Å, and a polysilicon layer thickness is in a range from about 1000 Å to about 2500 Å. In addition, for a typical 4-gas, fluorine-based etch chemistry, the polysilicon/TEOS selectivity is in a range from about 2 to about 5.8. This causes a problem when the photoresist layer is stripped because, as the polysilicon layer is etched thereafter, so too is the HM layer etched, and the thickness of the HM layer is small. This latter problem would also occur in plasma etch processes where PR layer 1050 is stripped, and a “self-cleaning” 3-gas, fluorine-based etch chemistry (such as, for example, and without limitation, Cl₂/CF₄/N₂) were used to etch polysilicon layer 1020. This is because the 3-gas, fluorine-based etch chemistry has an even poorer polysilicon/HM selectivity than does the 4-gas, fluorine-based etch chemistry.

In addition to the above-described problems, integrated circuit (“IC”) manufacturers utilize different designs for fabricating transistors in ICs. As a result, it becomes costly to develop etch processes that are tailored to meet the requirements of such different designs.

In light of the above, there is a need for one or more methods to solve one or more of the above-identified problems.

### SUMMARY OF THE INVENTION

One or more embodiments of the present invention advantageously solve one or more of the above-identified problems. Specifically, one embodiment of the present invention is a method used to fabricate an integrated circuit device on a wafer or substrate at a stage where a gate oxide is disposed over the wafer or substrate, a polysilicon layer is disposed thereover, a patterned hardmask is disposed thereover, a patterned antireflective coating is disposed thereover, and a patterned photoresist is disposed thereover, the method comprising steps of: (a) before stripping the photoresist, etching the polysilicon utilizing a first etch chemistry for a first period of time; and (b) etching the polysilicon utilizing a second etch chemistry for a second period of time.

### BRIEF DESCRIPTION OF THE FIGURE

FIG. 1 shows a block diagram of a film stack structure used to fabricate integrated circuits;

FIGS. 2A-2C show the film stack structure of FIG. 1 after various steps of an etch process that is carried out in accordance with one embodiment of the present invention; and

FIG. 3 shows a graph which illustrates various embodiments of the present invention.

### DETAILED DESCRIPTION

One or the embodiments of the present invention provide a method for an etch process that is applied to film stack structure 1400 shown in FIG. 1. A typical such film stack comprises: photoresist (“PR”) layer 1050 having a thickness in a range from about 3000 to about 5000 Å; BARC layer 1040 (“bottom antireflective coating,” an organic antireflective coating that is typically produced by a spin-on process in accordance with any one of a number of methods that are well known to those of ordinary skill in the art) having a thickness in a range from about 600 to about 1300 Å or DARC layer 1040 (“dielectric antireflective coating,” for example, a SiON (siliconoxynitride) layer that is deposited in accordance with any one of a number of methods that are well known to those of ordinary skill in the art) having a thickness in a range from about 200 to about 350 Å; hardmask layer 1030 (“HM,” for example, and without limitation, a silicon oxide layer formed using a deposition process wherein TEOS is a precursor in accordance with any one of a number of methods that are well known to those of ordinary skill in the art, or a silicon nitride layer) having a thickness in a range from about 350 to about 1000 Å; and polysilicon layer 1020 having a thickness in a range from about 1000 to about 2500 Å. This film stack is formed over gate oxide (“Gox”) layer 1010 that is formed on substrate 1000.

In accordance with one or more embodiments of the present invention, one or more of the following etch processes are carried out in a processing tool such as a DPS (“decoupled plasma source”) polysilicon etch tool that is available from Applied Materials, Inc. of Santa Clara, Calif. (a “DPS” tool). As is known, the DPS tool is an inductively coupled RF plasma reactor that generates and sustains a plasma utilizing an induction coil overlying the ceiling of an etch processing chamber that is powered by a source RF power supply which supplies a source power W_{S} (in watts) at a frequency of about 12.56 MHz. The DPS tool also includes a wafer pedestal (to support a wafer or substrate during processing) that is powered by an RF power supply which supplies a bias power W_{b} (in watts) at a frequency of about 13.56 MHz to provide a bias electric field that is used to control physical components of etching. The wafer pedestal also includes an electrostatic chuck that holds the wafer securely, and the wafer pedestal flows a gas, for example, He, across a backside of the wafer (“backside cooling gas”) to conduct heat between the wafer and the wafer pedestal. In this manner the wafer pedestal acts as a heat sink.

One or more embodiments of the present invention include one or more of the following process components or building blocks. The order of carrying out the process components or building blocks will be discussed after the process components or building blocks are described. Process component 1 (“PC1”) is an optional trim etch process that makes photoresist pattern lines thinner. As is well known, this is an essentially isotropic etch process, i.e., it comprises a substantially chemical etch component. In accordance with one embodiment of the present invention, the trim etch process chemistry is a plasma etch process that utilizes an O₂-based chemistry whose CD (“critical dimension”) loss for dense/isolated features is adjustable for various structural conditions by varying process parameters such as, for example, and without limitation, O₂ flow, and source and bias power. Appropriate process parameters for use in a particular case can be determined routinely by one of ordinary skill in the art without undue experimentation. In accordance with one such embodiment of the trim etch process, an O₂-based chemistry includes HBr, O₂, and Ar. In accordance with one embodiment of the present invention, a process recipe for the trim etch process for a 200 mm chamber (i.e., a chamber having a volume of about 35 liters) DPS tool includes: a flow rate in a range from about 10 to 200 sccm for HBr, a flow rate in a range from about 10 to about 100 sccm for O₂; and a flow rate in a range from about 10 to about 200 sccm for Ar; a chamber pressure in a range from about 2 to about 20 mT; a power applied to the induction coil in a range from about 100 to about 1000 Wₛ to generate and maintain a plasma in the chamber; a power applied to the wafer pedestal in a range from about 0 to about 300 W_{b}; and the temperature of the wafer pedestal is maintained in a range from about 30° C. to about 80° C. In accordance with at least some of such embodiments, a ratio of flow rates for HBr/O₂ is in a range from about 0.5:1 to about 2:1. In particular, in accordance with one of such embodiments, one might use about equal flow rates for HBr and O₂ (for example, and without limitation, about 40 sccm), and a larger flow of Ar (for example, and without limitation, about 80 sccm).

Process component 2 (“PC2”) is a hardmask open etch process. In accordance with one or more embodiments of the present invention, the hardmask open etch process is a plasma etch process that utilizes a passivation etch chemistry such as, for example, and without limitation, a CHₓF_{y} etch chemistry wherein the ratio of H/F in CHₓF_{y} determines photoresist/hardmask selectivity. In accordance with one embodiment of the present invention, a process recipe for an oxide hardmask open etch process for the 200 mm chamber DPS tool includes: a flow rate in a range from about 20 to about 200 sccm for CF₄; a flow rate in a range from about 0 to about 100 sccm for CHF₃; a flow rate in a range from about 0 to about 100 sccm for CH₂F₂; and a flow rate in a range from about 0 to about 200 sccm for Ar; a chamber pressure in a range from about 2 to about 20 mT; a power applied to the induction coil in a range from about 200 to about 1000 Wₛ to generate and maintain a plasma in the chamber; a power applied to the wafer pedestal in a range from about 10 to about 300 W_{b}; and a temperature of the wafer pedestal maintained in a range from about 30° C. to about 80° C. In accordance with at least some of such embodiments, a ratio of flow rates for CHF₃/CF₄ is in a range from about 0 to about 1.5:1; and a ratio of flow rates for CH₂F₂/CF₄ is in a range from about 0 to about 1.5:1. In accordance with another such embodiment, a process recipe for the hardmask open etch process for the 200 mm chamber DPS tool includes: a flow rate in a range from about 10 to about 100 seem for CH₂F₂; a flow rate in a range from about 10 to about 100 sccm for O₂, a flow rate in a range from about 10 to about 200 seem for Ar; a chamber pressure in a range from about 2 to 20 mT; a power applied to the induction coil in a range from about 200 to about 1000 Wₛ to generate and maintain a plasma in the chamber; a power applied to the wafer pedestal in a range from about 10 to about 300 W_{b}; and a temperature of the wafer pedestal maintained in a range from about 30° C. to about 80° C. In accordance with at least some of such embodiments, a ratio of flow rates for O₂/CH₂F₂ is in a range from about 0.2:1 to about 2:1. In accordance with other such embodiments, the hardmask open etch utilizes polymerizing agents such as, for example, and without limitation, CH₂F₂, C₄F₈, CHF₃, and C₄F₆ and diluents such as He.

Process component 3 (“PC3”) is a 3-gas, fluorine-based, etch chemistry, main etch, plasma etch process for polysilicon. Advantageously, this is a self-cleaning chemistry. In accordance with one or more embodiments of the present invention, the 3-gas, fluorine-based etch chemistry is a CF₄/Cl₂N₂ chemistry. This etch chemistry produces a fluorine-rich etch process that: (a) has an n-doped/p-doped etch-rate-ratio (“ERR”)˜1; (b) is indiscriminate between n-doped and p-doped polysilicon; (c) has low selectivity to oxide; (d) has low selectivity to hardmask, for example, a TEOS oxide HM layer or a silicon nitride HM layer; and (e) may leave microtrenches. Because of its low selectivity to the HM layer, in accordance with one or more embodiments of the present invention, this etch step is performed prior to stripping the photoresist layer. In accordance with one such embodiment of the present invention, a process recipe for a 3-gas, fluorine-based etch chemistry for the 200 mm chamber DPS tool to etch at least a first part of polysilicon layer 1020 with photoresist layer 1050 in place includes: a flow rate in a range from about 20 to about 200 sccm for CF₄; a flow rate in a range from about 0 to about 100 sccm for Cl₂; a flow rate in a range from about 0 to about 100 sccm for N₂; a chamber pressure in a range from about 2 to about 20 mT; a power applied to the induction coil in a range from about 200 to about 1000 Wₛ to generate and maintain a plasma in the chamber; a power applied to the wafer pedestal in a range from about 10 to about 300 W_{b}; and a temperature of the wafer pedestal maintained in a range from about 30° C. to about 80° C. In accordance with at least some of such embodiments, a ratio of flow rates for CF₄/Cl₂ is in a range from about 0.5:1 to about 5:1.

Process component 4 (“PC4”) is a 4-gas, fluorine-based, etch chemistry, main etch, plasma etch process for polysilicon. Advantageously, this is a self-cleaning chemistry. In accordance with one or more embodiments of the present invention, the 4-gas, fluorine-based, etch chemistry is an HBr/Cl₂/CF₄/He-O₂ chemistry. This etch chemistry produces an etch process which: (a) has an n-doped/p-doped ERR that is in a range from about 1.05 to about 1.1; (b) a PR/polysilicon selectivity in a range from about 2 to about 3; (c) a HM/polysilicon selectivity in a range from about 5 to about 10; and (d) may leave feet. In accordance with one such embodiment of the present invention, a process recipe for a 4-gas, fluorine-based, etch chemistry for the 200 mm chamber DPS tool to etch a remainder of polysilicon layer 1030 after a photoresist strip process includes: a flow rate in a range from about 10 to about 200 sccm for Cl₂; a flow rate in a range from about 0 to about 200 sccm for HBr; a flow rate in a range from about 0 to about 50 sccm for He—O₂; a flow rate in a range from about 0 to about 200 sccm for CF₄; a chamber pressure in a range from about 2 to about 25 mT; a power applied to the induction coils in a range from about 100 to about 1000 Wₛ to generate and maintain a plasma in the chamber; a power applied to the wafer pedestal in a range from about 10 to about 300 W_{b}; and a temperature of the wafer pedestal maintained in a range from about 30° C. to about 80° C. In accordance with at least some of such embodiments, a ratio of flow rates for CF₄/Cl₂ is in a range from about 0 to about 1:1; and a ratio of flow rates for Cl₂/HBr is in a range from about 0 to about 1:1. Note that, typically: (a) the 3-gas, fluorine-based etch chemistry is richer in fluorine than the 4-gas, fluorine-based etch chemistry; and (b) the etch rate of polysilicon using the 3-gas, fluorine-based etch chemistry typically is faster than the etch rate of polysilicon using the 4-gas, fluorine-based etch chemistry.

Process component 5 (“PC5”) is a photoresist strip and antireflective coating removal process. In accordance with one or more embodiments of the present invention, this process is an in-situ, plasma etch, photoresist strip process that utilizes, for example, and without limitation, an O₂ chemistry and results in little or no polysilicon or dielectric attack. In accordance with one such embodiment of the present invention, a process recipe for the O₂ chemistry photoresist strip process using the 200 mm chamber DPS tool includes: a flow rate in a range from about 10 to about 500 sccm for O₂; a chamber pressure in a range from about 2 to about 40 mT; a power applied to the induction coil in a range of about 300 to about 1200 Wₛ to generate and maintain a plasma in the chamber; a power applied to the wafer pedestal in a range from about 0 to about 200 W_{b}; and a temperature of the wafer pedestal maintained in a range from about 30° C. to about 80° C. Advantageously, such a process recipe will provide a high flow rate of O₂ and a high power applied to the plasma to provide a high throughput etch. In alternative embodiments, the photoresist strip process may be an ex-situ strip process that is carried out in any one of a number of commercially available strip chambers. As those of ordinary skill in the art will readily appreciate, the strip process of PC5 will also remove BARC layer 1040. However, if film stack structure 1400 shown in FIG. 1 has been fabricated using DARC layer 1040 instead of BARC layer 1040, then PC5 may include a process step that will remove DARC layer 1040. For example, such a process step may include a plasma etch process step like that described above for PC2 utilizing CF₄/Ar. Alternatively, such a process step may include a wet etch process utilizing, for example, HF which etches oxide and stops on silicon.

Process component 6 (“PC6”) is an optional breakthrough etch process that cleans residues left on the surface to be etched. For example, and without limitation, this process step may clean oxide left on the surface after the previous photoresist strip process. In accordance with one or more embodiments of the present invention, the breakthrough etch process is a plasma etch process that utilizes a CF₄/Ar chemistry to eliminate a transition region. In accordance with one such embodiment, a process recipe for the breakthrough etch process using the 200 mm chamber DPS tool includes: a flow rate in a range from about 10 to about 200 sccm for CF₄; a flow rate in a range from about 10 to about 200 sccm for Ar; chamber pressure in a range from about 2 to about 25 mT; a power applied to the induction coil in a range from about 100 to about 1000 Wₛ to generate and maintain a plasma in the chamber; a power applied to the wafer pedestal in a range from about 10 to about 300 W_{b}; and a temperature of the wafer pedestal maintained in a range from about 30° C. to about 80° C.

Process component 7 (“PC7”) is an optional “soft-landing” etch process. As is well known, main etch processes are designed to provide good etch profiles, however, their selectivity is not optimal. As a result, they may leave “feet” at the bottom of the etch profile that affect critical dimensions (“CDs”). As is also well known, a soft-landing etch process is designed to “pull-in” or remove the feet, and thereby, improve CD. However, its selectivity to oxide is not optimal. As such, the soft-landing etch process is a compromise between the ability to remove feet, and low selectivity. In accordance with one or more embodiments of the present invention, the soft-landing etch process is a plasma etch process that utilizes an HBr/Cl₂/O₂ chemistry to provide a good profile and reasonable gate oxide selectivity. In accordance with one such embodiment, a process recipe for the soft-landing etch process using the 200 mm chamber DPS tool includes: a flow rate in a range from about 10 to about 200 sccm for HBr; a flow rate in a range from about 10 to about 200 sccm for Cl₂; a flow rate in a range from about 10 to about 200 sccm for O₂; chamber pressure in a range from about 2 to about 25 mT; a power applied to the induction coil in a range from about 100 to about 1000 Wₛ to generate and maintain a plasma in the chamber; a power applied to the wafer pedestal in a range from about 10 to about 300 W_{b}; and a temperature of the wafer pedestal maintained in a range from about 30° C. to about 80° C. In accordance with at least some of such embodiments, a ratio of flow rates for O₂/HBr is in a range from about 0.2 to about 1:1; and a ratio of flow rates for Cl₂/HBr is in a range from about 0 to about 1:1.

Lastly, process component 8 (“PC8”) is an optional overetch process to complete the etch. In accordance with one or more embodiments of the present invention, the overetch process is a plasma etch process that utilizes an HBr/O₂ chemistry to provide good Gox selectivity. In accordance with one such embodiment, a process recipe for the overetch process using the 200 mm chamber DPS tool includes: a flow rate in a range from about 10 to about 200 sccm for HBr; a flow rate in a range from about 10 to about 200 sccm for O₂; chamber pressure in a range from about 2 to about 90 mT; a power applied to the induction coil in a range from about 100 to about 1000 Wₛ to generate and maintain a plasma in the chamber; a power applied to the wafer pedestal in a range of about 10 to about 300 W_{b}; and a temperature of the wafer pedestal maintained in a range from about 30° C. to about 80°C. In accordance with at least some of such embodiments, a ratio of flow rates for HBr/O₂ is in a range from about 4:1 to about 100:1.

For a 300 mm chamber DPS tool, for the above-described embodiments, the flow rates may be scaled to be a factor of about 2 larger than for the 200 mm chamber; the source power may be scaled to be about a factor of 1 larger than for the 200 mm chamber; and the bias power may be scaled to be about a factor of about 1.5—2 larger than for the 200 mm chamber. It should also be noted that embodiments of the present invention may also be carried out in a processing tool such as a DPS II (“decoupled plasma source”) polysilicon etch tool that is available from Applied Materials, Inc. of Santa Clara, Calif. The DPS II tool is an inductively coupled RF plasma reactor that generates and maintains a plasma utilizing two solenoidal induction coils overlying the ceiling of the chamber that are powered by a source RF power supply which supplies a source power W_{S} (in watts) at a frequency of about 13.56 MHz. The source RF power supply applies power W_{S} to the outer and inner coils through a software-driven current splitter. The DPS II tool also includes a wafer pedestal (to support a wafer or substrate during processing) that is powered by an RF power supply which supplies a bias power W_{b} (in watts) at a frequency of about 13.56 MHz to provide a bias electric field that is used to control physical components of etching. The wafer pedestal also includes an electrostatic chuck that holds the wafer securely, and the wafer pedestal flows a gas, for example, He, across a backside of the wafer (“backside cooling gas”) to conduct heat between the wafer and the wafer pedestal. In this manner the wafer pedestal acts as a heat sink. In particular, in one version of the DPS II tool, the backside cooling gas flows in two zones having different backside cooling gas pressures to better control temperature across the wafer. Lastly, the DPS II tool has a center gas feed. The embodiments described above in regard to use of a DPS tool can readily be converted to use of a DPS II tool, and a ratio (Rₐ) of power supplied to the outer coil and to the inner coil from the source RF power supply W_{S} can be determined routinely by one of ordinary skill in the art without undue experimentation. In particular, for a process step PC2 that is carried out in a DPS II tool, as described in detail in an application entitled “Methods for Enhancing Critical Dimension Uniformity after Etch” which is assigned to the assignee of the present invention, and which is incorporated herein by reference, preferably, Rₐ>1.

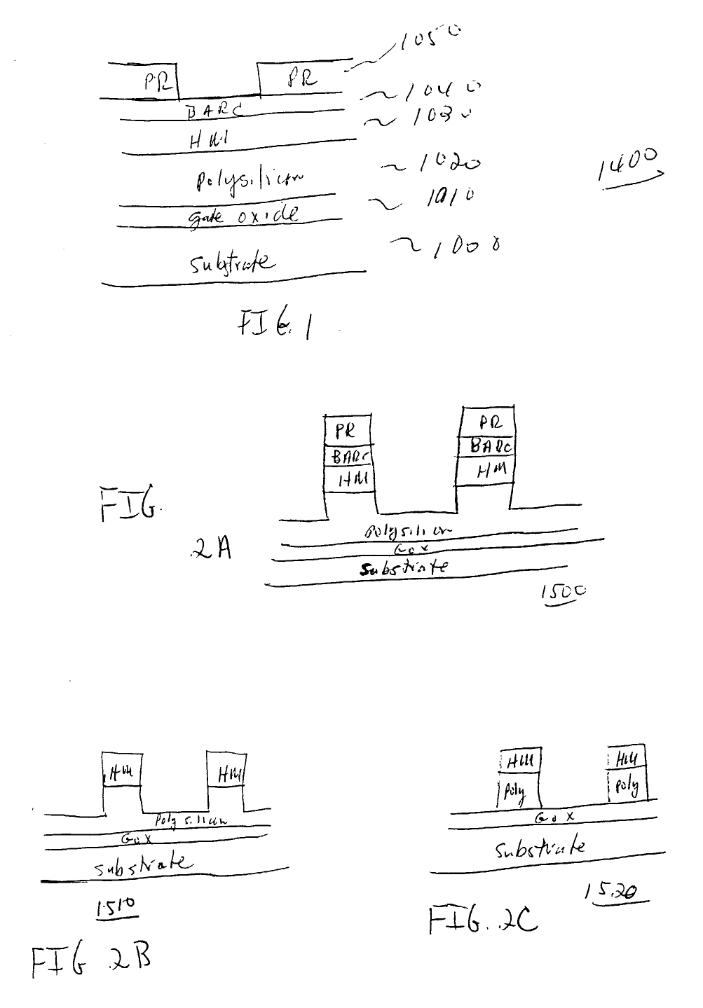

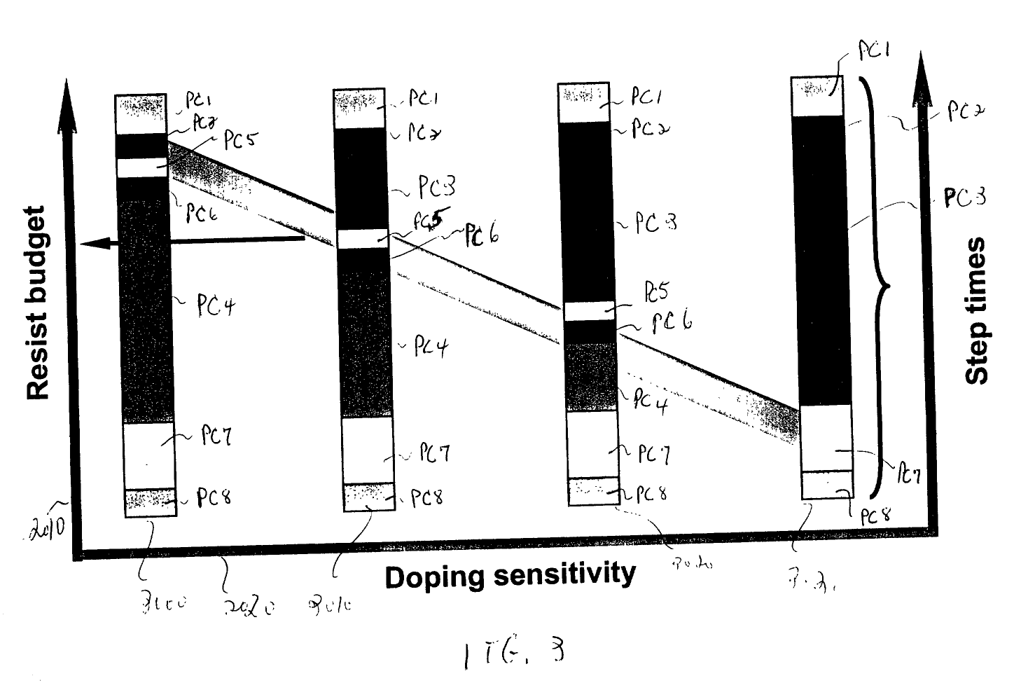

FIGS. 2A-2C show the film structure of FIG. 1 after various steps of an etch process that is carried out in accordance with one embodiment of the present invention. As shown in FIG. 2A, structure 1500 is obtained from structure 1400 shown in FIG. 1 after process steps PC1, PC2, and PC3 have been carried out. As shown in FIG. 2B, structure 1510 is obtained from structure 1500 after process steps PC5, PC6, and PC4 have been carried out. Finally, as shown in FIG. 2C, structure 1520 is obtained from structure 1510 after process steps PC7 and PC8 have been carried out.

In accordance with one or more embodiments of the present invention, the above-described process components serve as building block processes for an etch process that can be tailored to provide desired or predetermined etch results for various integrated circuit (“IC”) designs. In accordance with one or more such embodiments, a user may vary the length of time of the various building block processes to achieve a desired or predetermined result. For example, in accordance with one set of embodiments designed to meet requirements of varying IC designs, a particular trim etch process (PC1), a particular hardmask open etch process (PC2), a particular in-situ, photoresist strip process (PC5), a particular breakthrough etch process (PC6), a particular soft-landing etch process (PC7), and a particular overetch process (PC8) are substantially the same for various embodiments, i.e., the length of time for each etch process, for each of these components, will remain substantially the same for each process component across the various embodiments. However, for such embodiments, the use, if any, and the length of time of, a particular 3-gas, fluorine-based, etch chemistry, main etch process for polysilicon (PC3), and the use, if any, and the length of time of, a particular 4-gas, fluorine-based, etch chemistry, main etch process for polysilicon (PC4) are tailored for specific IC device designs.

In accordance with one such embodiment, tailoring the length of time for PC3 and PC4 depends on the amount of doping sensitivity of polysilicon layer 1030 required by a specific IC design. For example, the higher the doping level of polysilicon layer 1030, the longer the length of time for PC3 (i.e., the 3-gas, fluorine-based etch chemistry) which is not sensitive to doping level. Conversely, the lower the doping level of polysilicon layer 1030, the longer the length of time for PC4 (i.e., the 4-gas, fluorine-based etch chemistry). In particular, in accordance with such embodiments of the present invention, enough of polysilicon layer 1020 is etched using PC3 to etch beyond a depth to which the doping reaches (using photoresist layer 1050 to protect hardmask layer 1030). For example, if polysilicon layer 1020 is doped, but not annealed, the dopant resides mainly at the top of polysilicon layer 1020. Although a doped portion of polysilicon layer 1030 may be etched readily using a chlorine-based chemistry, this may produce undercutting in n-doped polysilicon. Advantageously, the etch process of PC3 prevents undercutting of the polysilicon (for example, and without limitation, CF₄—Ar, CF₄—He, and CF₄—N₂ produces some passivation, then chlorine may be added in PC4).

FIG. 3 shows a graph which illustrates various embodiments of the present invention. As shown in FIG. 3, process step time is plotted along axis 2000, photoresist budget (i.e., thickness) is plotted along axis 2010, and doping sensitivity is plotted along axis 2020. As shown in FIG. 3, for embodiment 3000, the etch process includes, in order, PC1, PC2, PC5, PC6, PC4, PC7, and PC8. For embodiment 3010, the etch process includes, in order, PC1, PC2, PC3, PC5, PC6, PC4, PC7, and PC8. For embodiment 3020, the etch process includes, in order, PC1, PC2, PC3, PC5, PC6, PC4, PC7, and PC8. For embodiment 3030, the etch process includes, in order, PC1, PC2, PC3, PC7, and PC8. As one can readily appreciate from FIG. 3, as the doping sensitivity increases, i.e., higher doping concentrations, the length of time for PC3 relative to PC4 increases. Appropriate ranges of lengths of times for the various process components for specific device designs may be determined routinely by one of ordinary skill in the art without undue experimentation.

In accordance with alternative embodiments of the present invention, tailoring the length of time for PC3 and PC4 depends on optimizing CD by matching microtrenches produced by PC3 with feet produced by PC4. Appropriate ranges of lengths of times for the various process components for specific device designs may be determined routinely by one of ordinary skill in the art without undue experimentation.

In accordance with further alternative embodiments of the present invention, tailoring the length of time for PC3 and PC4 depends on the photoresist thickness. For example, it may be advantageous to utilize PC3 for as long as possible so that photoresist layer 1050 protects hardmask layer 1030. As a result, this will increase the thickness of hardmask layer 1030 remaining after polysilicon layer 1020 is completely etched. Advantageously, this increases the hardmask/polysilicon selectivity margin for the last polysilicon etch process step.

Those skilled in the art will recognize that the foregoing description has been presented for the sake of illustration and description only. As such, it is not intended to be exhaustive or to limit the invention to the precise form disclosed. For example, although certain dimensions were discussed above, they are merely illustrative since various designs may be fabricated using the embodiments described above, and the actual dimensions for such designs will be determined in accordance with circuit requirements.

What is claimed is:

1. A method used to fabricate an integrated circuit device on a wafer or substrate at a stage where a gate oxide is disposed over the wafer or substrate, a polysilicon layer is disposed thereover, a patterned hardmask is disposed thereover, a patterned antireflective coating is disposed thereover, and a patterned photoresist is disposed thereover, the method comprising steps of:
before stripping the photoresist, etching the polysilicon utilizing a first etch chemistry for a first period of time; and
etching the polysilicon utilizing a second etch chemistry for a second period of time.

2. The method of claim 1 which further comprises steps of:
before etching utilizing a second chemistry, stripping the photoresist and the antireflective coating.

3. The method of claim 1 wherein the first etch chemistry is relatively insensitive to doping of the polysilicon, and the second etch chemistry is sensitive to doping of the polysilicon.

4. The method of claim 1 wherein the first period and the second period vary as a function of doping sensitivity in the polysilicon.

5. The method of claim 4 wherein the first time increases relative to the second time as the doping sensitivity increases.

6. The method of claim 1 wherein the first period and the second period vary as a function of thickness of the photoresist.

7. The method of claim 6 wherein the first time decreases relative to the second time as the thickness of the photoresist decreases.

8. The method of claim 1 wherein the first etch chemistry is a 3-gas, fluorine-based, etch chemistry, and the second etch chemistry is a 4-gas, fluorine-based, etch chemistry.

9. The method of claim 1 wherein the 3-gas, fluorine-based, etch chemistry is a CF₄/Cl₂/N₂ chemistry, and the 4-gas, fluorine-based, etch chemistry is an HBr/Cl₂/CF₄/He-O₂ chemistry.

10. The method of claim 1 wherein the first time and the second time are determined by matching microtrenches produced by the first step of etching the polysilicon with feet produced by the second step of etching the polysilicon.

11. A method used to fabricate an integrated circuit device on a wafer or substrate at a stage where a gate oxide is disposed over the wafer or substrate, a polysilicon layer is disposed thereover, a hardmask is disposed thereover, an antireflective coating is disposed thereover, and a patterned photoresist is disposed thereover, the method comprising steps of:
etching to open the hardmask;
etching the polysilicon utilizing a first fluorine-based etch chemistry for a first period of time;
stripping the photoresist and the antireflective coating;
etching the polysilicon utilizing a second fluorine-based etch chemistry for a second period of time; and
overetching the polysilicon.

12. The method of claim 11 which further comprises first trim etching the patterned photoresist utilizing an HBr/O₂ chemistry.

13. The method of claim 12 wherein the trim etching utilizes a flow rate in a range from about 10 to 200 sccm for HBr; and a flow rate in a range from about 10 to about 100 sccm for O₂.

14. The method of claim 12 wherein the trim etching utilizes a ratio of flow rates for HBr/O₂ in a range from about 0.5:1 to about 2:1.

15. The method of claim 11 wherein the hardmask open etch utilizes a passivation etch chemistry.

16. The method of claim 15 wherein the passivation chemistry is a CHₓF_{Y} etch chemistry.

17. The method of claim 16 wherein the CHₓF_{y} etch chemistry utilizes a flow rate in a range from about 20 to about 200 sccm for CF₄, a flow rate in a range from about 0 to about 100 sccm for CHF₃; and a flow rate in a range from about 0 to about 100 sccm for CH₂F₂.

18. The method of claim 16 wherein the CHₓF_{Y} etch chemistry utilizes a ratio of flow rates for CHF₃/CF₄ in a range from about 0 to about 1.5: 1; and a ratio of flow rates for CH₂F₂/CF₄ in a range from about 0 to about 1.5:1.

19. The method of claim 11 wherein the first fluorine-based etch chemistry is a 3-gas, fluorine-based etch chemistry.

20. The method of claim 19 wherein the step of 3-gas chemistry etching utilizes a flow rate in a range from about 20 to about 200 sccm for CF₄; a flow rate in a range from about 0 to about 100 sccm for Cl₂; and a flow rate in a range from about 0 to about 100 sccm for N₂.

21. The method of claim 19 wherein the step of 3-gas chemistry etching utilizes a ratio of flow rates for CF₄/Cl₂ in a range from about 0.5:1 to about 5:1.

22. The method of claim 11 wherein the second fluorine-based etch chemistry is a 4-gas fluorine-based etch chemistry.

23. The method of claim 22 wherein the step of 4-gas chemistry etching utilizes a flow rate in a range from about 10 to about 200 sccm for Cl₂; a flow rate in a range from about 0 to about 200 sccm for HBr; a flow rate in a range from about 0 to about 50 sccm for He-O₂; and a flow rate in a range from about 0 to about 200 sccm for CF₄.

24. The method of claim 22 wherein the step of 4-gas chemistry etching utilizes a ratio of flow rates for CF₄/Cl₂ in a range from about 0 to about 1:1; and a ratio of flow rates for Cl₂/HBr is in a range from about 0 to about 1:1.

25. The method of claim 11 wherein the step of stripping comprises etching utilizing an oxygen chemistry.

26. The method of claim 11 which further comprises a step of breakthrough etching before etching the polysilicon utilizing a second fluorine-based etch chemistry for a second period of time, which breakthrough etching comprises etching utilizing a CF₄ chemistry.

27. The method of claim 26 wherein the step of breakthrough etching utilizes a flow rate in a range from about 10 to about 200 sccm for CF₄.

28. The method of claim 11 which further comprises a step of soft-landing etching after etching the polysilicon utilizing a second fluorine-based etch chemistry for a second period of time, which soft-landing etching comprises etching utilizing an HBr/Cl₂/O₂ chemistry.

29. The method of claim 28 wherein the step of soft-landing etching utilizes a flow rate in a range from about 10 to about 200 sccm for HBr; a flow rate in a range from about 10 to about 200 sccm for Cl₂; and a flow rate in a range from about 10 to about 200 sccm for O₂.

30. The method of claim 28 wherein the step of soft-landing etching utilizes a ratio of flow rates for O₂HBr in a range from about 0.2 to about 1:1; and a ratio of flow rates for Cl₂/HBr in a range from about 0 to about 1:1.

31. The method of claim 11 wherein the step of overetching comprises etching utilizing an HBr/O₂ chemistry.

32. The method of claim 31 wherein the step of overetching utilizes a flow rate in a range from about 10 to about 200 sccm for HBr; and a flow rate in a range from about 10 to about 200 sccm for O₂.

33. The method of claim 32 wherein the step of overetching utilizes a ratio of flow rates for HBr/O₂ in a range from about 4:1 to about 100:1.

34. The method of claim 16 wherein the CHₓF_{Y} etch chemistry utilizes a flow rate in a range from about 10 to about 100 sccm for CH₂F₂; and a flow rate in a range from about 10 to about 100 sccm for O₂.

35. The method of claim 16 wherein the CHₓF_{Y} etch chemistry utilizes a ratio of flow rates for O₂/CH₂F₂ in a range from about 0.2:1 to about 2:1
